(19) United States
(12) Patent Application Publication
(10) Pub. No.: US 2011/0285566 A1
(43) Pub. Date: Nov. 24, 2011

(54) DIGITAL-TO-ANALOG CONVERTER AND DIGITAL-TO-ANALOG CONVERTING DEVICE

(75) Inventors: Yosuke GOTO, Osaka (JP); Fumihito Inukai, Kyoto (JP)

(73) Assignee: PANASONIC CORPORATION, Osaka (JP)

(21) Appl. No.: 13/084,222

(22) Filed: Apr. 11, 2011

Related U.S. Application Data
(63) Continuation of application No. PCT/JP2010/005674, filed on Sep. 17, 2010.

(30) Foreign Application Priority Data
May 19, 2010 (JP) 2010-114928

(51) Int. Cl. H03M 3/02; H03M 1/66

(52) U.S. Cl. 341/143; 341/150

(57) ABSTRACT

A D/A converter comprises a first switch unit for performing switching to provide connection and disconnection between one terminals of the plurality of sampling capacitive elements and the corresponding plurality of input terminals, and to provide connection and disconnection between the other terminals of the plurality of sampling capacitive elements and a reference voltage source for generating a reference voltage; a second switch unit for performing switching to provide connection and disconnection between the other terminals and an inverting input terminal of the operational amplifier, to provide connection and disconnection between one terminals of the sampling capacitive elements and to close and open an electric path through which a voltage according to a voltage of the sampling capacitive elements, is output to an output terminal of the operational amplifier, in accordance with the switching of the first switch unit; and a resistive element provided on the electric path.

This is a continuation application under 35U.S.C. 111(a) of pending prior International application No. PCT/JP2010/005674, filed on Sep. 17, 2010. The disclosure of Japanese Patent Application No. 2010-114928 filed on May 19, 2010 including specification, drawings and claims is incorporated herein by reference in its entirety.

### BACKGROUND OF THE INVENTION

1. Field of the Invention

The present invention generally relates to a digital-to-analog (D/A) converter for converting a digital input signal into an analog output signal, and a digital-to-analog (D/A) converting device for performing digital-to-analog conversion after performing delta-sigma modulation. Particularly, the present invention relates to a switched-capacitor D/A converter and a switched-capacitor D/A converting device which operate at high speeds.

2. Description of the Related Art

D/A converters are required to have three characteristics, for example, a low power consumption, a low noise, and a low distortion. Especially, a D/A converter for use in an audio field must meet requirements of a lowest possible noise and a lowest possible distortion. A slight conversion error in an analog output signal would worsen these characteristics.

In the D/A converter, a capacitive element is charged according to a signal level of a digital input signal, and an operational amplifier outputs an analog output signal according to a charging voltage of the capacitive element. To achieve both a low noise and a low distortion in the D/A converter having such a configuration, there is known a configuration in which a path between an input terminal of a digital input signal and a capacitive element is coupled to an output terminal of the operational amplifier in connection of the capacitive element to an operational amplifier (see, e.g., Japanese Patent No. 3852721 Publication). In accordance with this configuration, since the capacitive element is provided in a negative feedback loop of the operational amplifier, it is possible to prevent the analog output signal from being affected by a parasitic capacitance of the operational amplifier, thereby reducing a D/A conversion error.

In such a D/A converter, however, a switch including an FET (field effect transistor) is typically used to provide connection and disconnection between the capacitive element and the operational amplifier. It is known that in the switch including the FET, a resistance value (ON-resistance value) in a state where the switch is closed (in ON-state) depends on a voltage between a gate terminal and a source or drain terminal.

To suppress a change in the ON-resistance value due to a change in the source or drain voltage, a configuration using a bootstrap switch is also known (e.g., Japanese Patent No. 4128545 Publication).

### SUMMARY OF THE INVENTION

FIG. 14 is graphical representation showing a change in the ON-resistance value of the above mentioned FET. In FIG. 14, an upper graph depicts that the source or drain voltage varies with a constant amplitude when a voltage of the gate terminal is constant, while a lower graph depicts a change in the ON-resistance value which occurs when the source or drain voltage is varying as indicated by the upper graph. Referring to FIG. 14, when the source or drain voltage (a voltage value of the analog output signal when the FET is used as the above switch) of the FET varies periodically, the ON-resistance value significantly changes. For example, as shown in the lower graph of FIG. 14, in the FET having a highest ON-resistance value of 2 kΩ, the ON-resistance value has a changing magnitude of about 1 kΩ, in a range where a maximum amplitude of the analog output signal is about 1 Vpp.

However, if the ON-resistance value of the switch changes in the D/A converter as disclosed in Japanese Patent No. 3852721 Publication, a voltage applied to the operational amplifier changes, causing overshooting, undershooting, ringing, etc., to be generated in the analog output signal. This leads to a distortion or a noise in the analog output signal.

In the bootstrap switch intended to suppress a change in the ON-resistance value as disclosed in Japanese Patent No. 4128545 Publication, since a plurality of transistors and a plurality of capacitive elements are necessary for each switch, a circuit area increases and electric power consumption increases, when this bootstrap switch is applied to the D/A converter including a plurality of switches.

The present invention has been developed to solve the above described problem, and an object of the present invention is to provide a D/A converter for preventing a distortion or a noise from being generated in an analog output signal due to an ON-resistance value of a switch, with a simple circuit configuration, and a D/A converting device including this D/A converter and configured to perform delta-sigma modulation.

A digital-to-analog converter of the present invention comprises a plurality of input terminals to which a plurality of bit signals constituting a digital signal are input, respectively; a plurality of sampling capacitive elements provided to correspond to the plurality of input terminals, respectively; a first switch unit for performing switching to connect one terminals of the plurality of sampling capacitive elements to the corresponding plurality of input terminals, respectively, and to disconnect the one terminals of the plurality of sampling capacitive elements from the corresponding plurality of input terminals, respectively, and performing switching to connect the other terminals of the plurality of sampling capacitive elements to a reference voltage source for generating a reference voltage and to disconnect the other terminals of the plurality of sampling capacitive elements from the reference voltage source; an operational amplifier having a non-inverting input terminal applied with the reference voltage of the reference voltage source; a second switch unit for performing switching to connect the other terminals of the plurality of sampling capacitive elements to an inverting input terminal of the operational amplifier, and to disconnect the other terminals of the plurality of sampling capacitive elements from the inverting input terminal, performing switching to connect the one terminals of the plurality of sampling capacitive elements to each other and to disconnect the one terminals of the plurality of sampling capacitive elements from each other, and performing switching to close and open an electric path through which a voltage according to a voltage of the plurality of sampling capacitive elements with the one terminals connected to each other, is output to an output terminal of the operational amplifier, in accordance with the switching of the first switch unit; and a resistive element provided on the electric path.

In accordance with this configuration, in a state where a connection is made in the first switch unit (the first switch unit is turned ON), the plurality of sampling capacitive elements are charged according to the signal levels of the plurality of bit signals constituting the digital input signal. Thereafter, when a disconnection is made in the first switch unit (first switch unit is turned OFF) and the second switch unit is turned ON, the electric path between the sampling capacitive elements and the operation amplifier is closed. Thereby, the operational amplifier outputs as an analog output signal, a voltage according to a charging voltage of the plurality of capacitive elements with the one terminals connected to each other. In this case, since the second switch unit and the resistive element are present on the closed electric path, a composite resistance value of the electric path which affects an output characteristic of the operational amplifier is a sum of a composite resistance value (ON-resistance value) of the second switch unit and a resistance value of the resistive element. In this configuration, since a change rate of the composite resistance value of the electric path is less than a change rate based on only the composite resistance value of the second switch unit in a configuration in which the resistive element is omitted, even when the composite resistance value of the second switch unit changes according to a voltage applied to the second switch unit. Because of this, the operational amplifier can output a more stable analog output signal. Therefore, with a simple configuration, it is possible to prevent a distortion or a noise from being generated in the analog output signal due to the ON-resistance value of the switch.

The resistive element may include a first resistive element provided on a first path connecting paths between the plurality of input terminals and the one terminals of the plurality of sampling capacitive elements to the output terminal of the operational amplifier; and the second switch unit may include an input-side second switch section provided on the first path and an output-side second switch section provided between the other terminals of the plurality of sampling capacitive elements and an inverting input terminal of the operational amplifier. In this configuration, since the first resistive element is connected in series with the output terminal of the operational amplifier, it is possible to more effectively prevent a distortion or a noise from being generated in the analog output signal which is the output voltage of the operational amplifier.

A ratio of a sum of a composite resistance value of the input-side second switch section and a resistance value of the first resistive element with respect to a maximum value of the composite resistance value of the input-side second switch section may be not less than 2 and not more than 20. The ratio may be not less than 12 and not more than 16. Thereby, it is possible to prevent a distortion or a noise from being generated in the analog output signal, while maintaining a response speed permitted in the D/A converter.

The input-side second switch section may include a plurality of switches corresponding to the plurality of sampling capacitive elements, respectively; and the first resistive element may include a plurality of first resistive elements, one ends of which are connected to the plurality of switches in the input-side second switch section, respectively, and the other ends of which are connected to the output terminal of the operational amplifier. In this configuration, since the plurality of first resistive elements are provided to correspond to the plurality of switches, respectively, it is possible to easily set the resistance values which are suitable for capacitances of the sampling capacitive elements or switch sizes (ON-resistance values).

The digital-to-analog converter may further comprise a feedback capacitive element provided between the inverting input terminal of the operational amplifier, and the output terminal of the operational amplifier. In this configuration, when the first switch unit is turned OFF and the second switch unit is turned ON, the sampling capacitive elements are connected in parallel with the feedback capacitive element, and distribution of the charge between the capacitive elements and the feedback capacitive element occurs in such a manner that a part of the charge stored in the sampling capacitive elements is transferred to the feedback capacitive element. Thus, the charge stored in the sampling capacitive elements is transferred to the feedback capacitive element through the first path without passing through the operational amplifier when the analog output signal is output. This can lessen current consumption in the operational amplifier.

The resistive element may include a second resistive element provided between the other terminals of the sampling capacitive elements and the inverting input terminal of the operational amplifier. In this configuration, since the second resistive element is connected in series with the inverting input terminal of the operational amplifier, an input voltage of the operational amplifier is stabilized. As a result, it is possible to prevent a distortion or a noise from being generated in the analog output signal.

The input-side second switch section may include a plurality of switches having different ON-resistance values, and the digital-to-analog converter may further comprise a selector circuit which detects a signal level of the digital input signal and selects a switch to be turned ON, from among the plurality of switches, based on a voltage value of the analog output signal which is predicted from the detected signal level. In this configuration, since discharging of the sampling capacitive element can be performed using a switch having a more suitable ON-resistance value according to the predicted voltage value of the analog output signal which is output from the operational amplifier, the operational amplifier can output a more stable analog output signal.

The resistive element may include a plurality of resistive elements having different resistance values, and the digital-to-analog converter further comprise a selector circuit which detects a signal level of the digital input signal and selects a resistive element to be connected, from among the plurality of resistive elements, based on a voltage value of the analog output signal which is predicted from the detected signal level. In this configuration, since discharging of the sampling capacitive element can be performed using a resistive element having a more suitable resistance value according to the predicted voltage value of the analog output signal which is output from the operational amplifier, the operational amplifier can output a more stable analog output signal.

A digital-to-analog converting device of the present invention comprises a digital interpolation filter for interpolating a digital input signal and outputting the interpolated digital input signal; a delta-sigma modulator for delta-sigma modulating the interpolated digital input signal; and a digital-to-analog converter having the above stated configuration, and configured to convert the delta-sigma modulated digital input signal into an analog signal.

In accordance with this configuration, since the D/A converter having the above configuration is used to convert the delta-sigma modulated digital input signal into the analog signal, the operational amplifier in the D/A converter can output a more stable analog output signal. Therefore, with a simple configuration, it is possible to prevent a distortion or a noise from being generated in the analog output signal due to the ON-resistance value of the switch.

The digital-to-analog converting device may further comprise a dynamic element matching section for performing a dynamic element matching process with respect to the delta-sigma modulated digital signal output from the delta-sigma modulator, the digital signal that has undergone the dynamic element matching process, being input to the digital-to-analog converter. Since the dynamic element matching process can suppress a variation in capacitances of the sampling capacitive elements in the D/A converter A, the D/A converter can output a more stable analog output signal.

The input-side second switch section may include a plurality of switches having different ON-resistance values, the resistive element may include a plurality of resistive elements having different resistance values; and the selector circuit may select a switch to be turned ON, from among the plurality of switches and a resistive element to be connected, from among the plurality of resistive elements, according to a sampling frequency used in the delta-sigma modulator. In this configuration, discharging of the sampling capacitive elements can be performed using a switch having a more suitable ON-resistance value and a resistive element having a more suitable resistance value according to the sampling frequency used in the delta-sigma modulator. Therefore, the operational amplifier can output a more stable analog output signal.

The present invention has been configured as described above, and achieves an advantage that it is possible to prevent a distortion or a noise from being generated in the analog output signal due to the ON-resistance value of the switch, with a simple configuration.

The above and further objects, features and advantages of the present invention will more fully be apparent from the following detailed description of preferred embodiments with accompanying drawings.

### BRIEF DESCRIPTION OF THE DRAWINGS

FIG. 1 is a circuit diagram showing a schematic configuration of a D/A converter according to Embodiment 1 of the present invention.

FIG. 2 is a graph showing operation timings of first and second switch units used in the D/A converter of FIG. 1.

FIG. 3 is a circuit diagram showing an exemplary configuration of a switch used in the D/A converter of FIG. 1.

FIG. 4 is a circuit diagram showing an equivalent circuit of the D/A converter of FIG. 1 during a second period.

FIG. 5 is a graph showing a change in a composite resistance value of a resistance value of an input-side second switch section and a resistance value of a resistive element, which change occurs due to a change in the resistance value of the input-side second switch section, in the D/A converter of FIG. 1.

FIG. 6 is a circuit diagram showing a schematic configuration of a D/A converter according to Embodiment 2 of the present invention.

FIG. 7 is a circuit diagram showing a schematic configuration of a D/A converter according to Embodiment 3 of the present invention.

FIG. 8 is a circuit diagram showing a schematic configuration of a D/A converter according to Embodiment 4 of the present invention.

FIG. 9 is a circuit diagram showing a schematic configuration of a D/A converter according to Embodiment 5 of the present invention.

FIG. 10 is a circuit diagram showing a schematic configuration of a D/A converter according to Embodiment 6 of the present invention.

FIG. 11 is a circuit diagram showing a schematic configuration of a D/A converter according to Embodiment 7 of the present invention.

FIG. 12 is a circuit diagram showing an exemplary schematic configuration of a D/A converting device incorporating the D/A converter of the present invention.

FIG. 13 is a circuit diagram showing another exemplary schematic configuration of the D/A converting device incorporating the D/A converter of the present invention.

FIG. 14 is a graph showing a change in an ON-resistance value of a field effect transistor (FET).

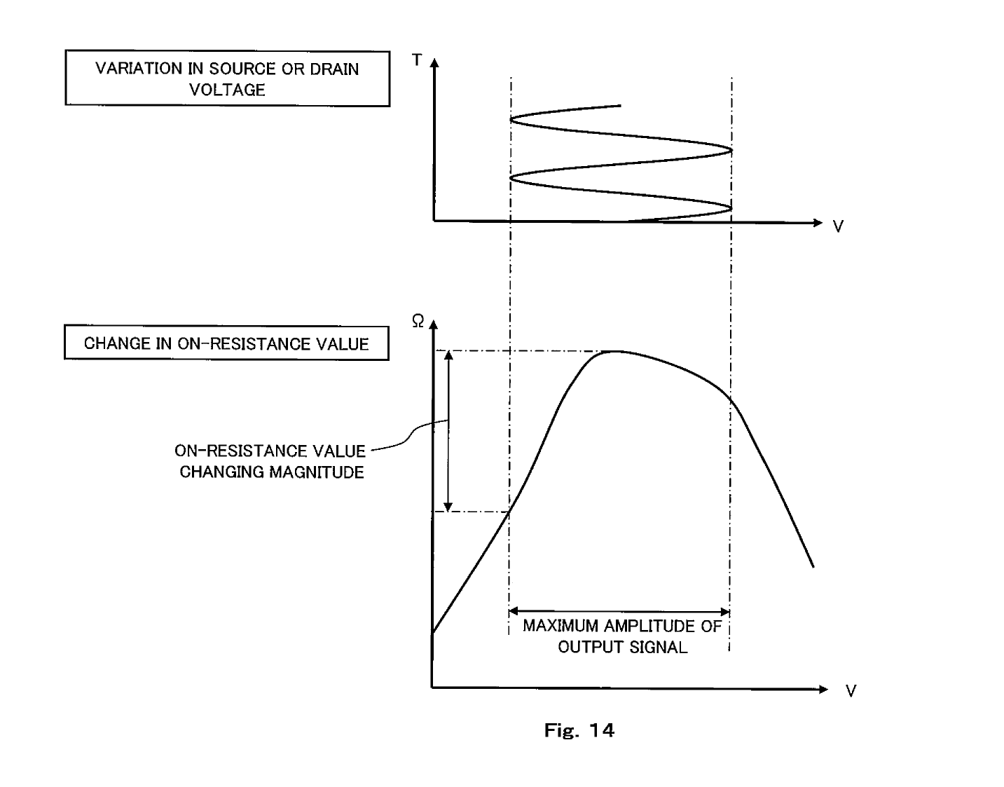

### DETAILED DESCRIPTION OF THE PREFERRED EMBODIMENTS

Hereinafter, preferred embodiments of the present invention will be described with reference to the drawings. Throughout the drawings, the same or corresponding constituents and components are designated by the same reference symbols and will not be described respectively.

### Embodiment 1

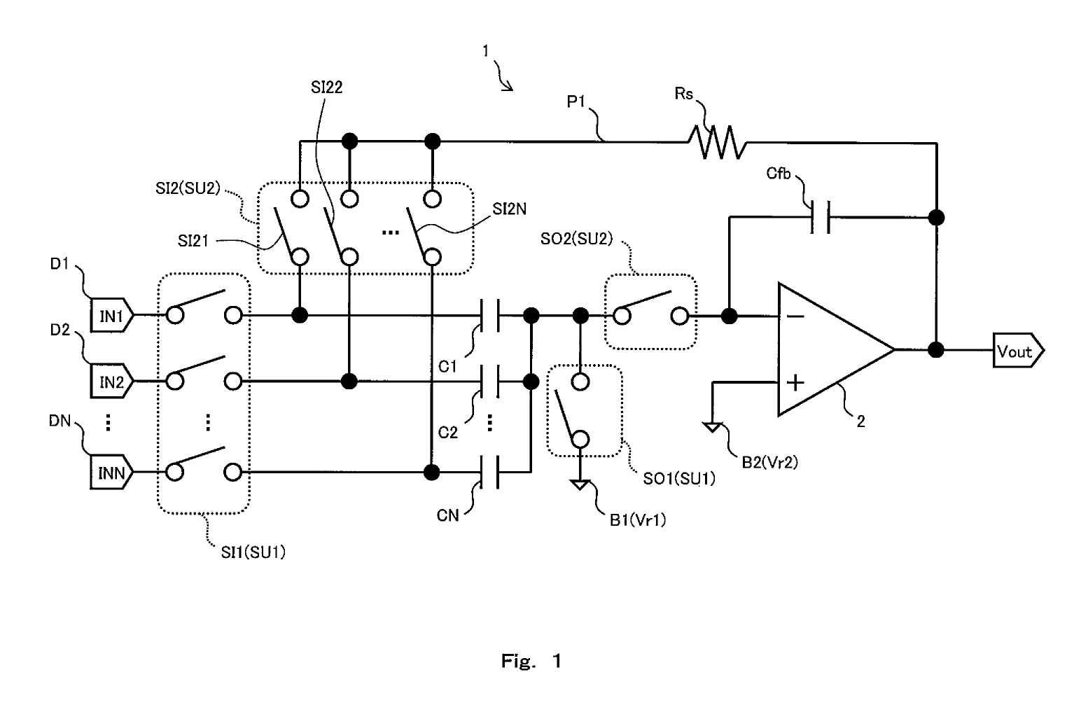

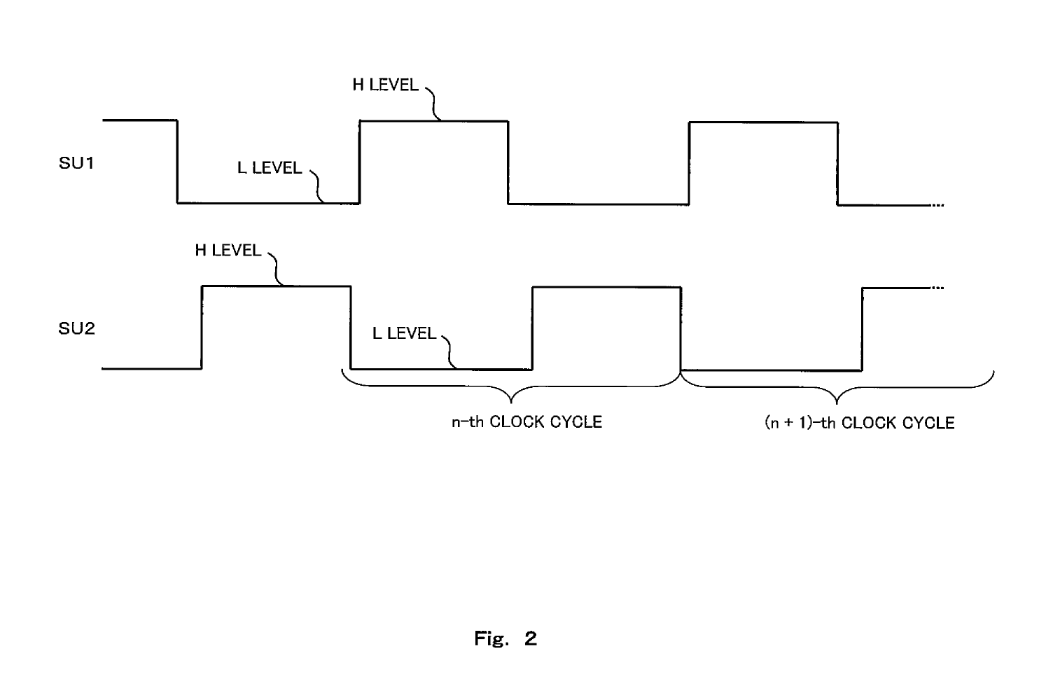

First of all, a digital-to-analog (D/A) converter according to Embodiment 1 of the present invention will be described. FIG. 1 is a circuit diagram showing a schematic configuration of a D/A converter according to Embodiment 1 of the present invention. FIG. 2 is a graph showing operation timings of first and second switch units used in the D/A converter of FIG. 1.

Referring now to FIG. 1, a D/A converter 1 of this embodiment is a switched-capacitor D/A converter, and includes a plurality of input terminals Di (i=1˜N) to which a plurality of bit signals INi (i=1˜N) constituting a digital input signal with a plurality of levels are input, and a plurality of sampling capacitive elements Ci (i=1˜N) provided to correspond to the plurality of input terminals Di, respectively. Each sampling capacitive element Ci is charged such that its charging voltage reaches a first reference voltage Vr1 according to a signal level (voltage Vr+ or Vr−) of a bit signal INi input through the corresponding input terminal Di. The first reference voltage Vr1 is generated by a first reference voltage source B1 connected in series with the sampling capacitive elements Ci. A first switch unit SU1 is provided between the plurality of input terminals Di (i=1˜N) provided to correspond to the plurality of bit signals INi, respectively, and one terminals of the plurality of corresponding sampling capacitive elements Ci, respectively, to perform switching to provide connection and disconnection between them. A first switch unit SU1 is further provided between the first reference voltage source B1 and the other terminals of the sampling capacitive elements Ci, to perform switching to provide connection and disconnection between them.

To be specific, the first switch unit SU1 includes an input-side first switch section SI1 provided between the plurality of input terminals Di and one terminals of the plurality of corresponding sampling capacitive elements Ci, and an output-side first switch section SO1 provided between the first reference voltage source B1 and the other terminals of the sampling capacitive elements Ci. Each switch includes a field effect transistor (FET).

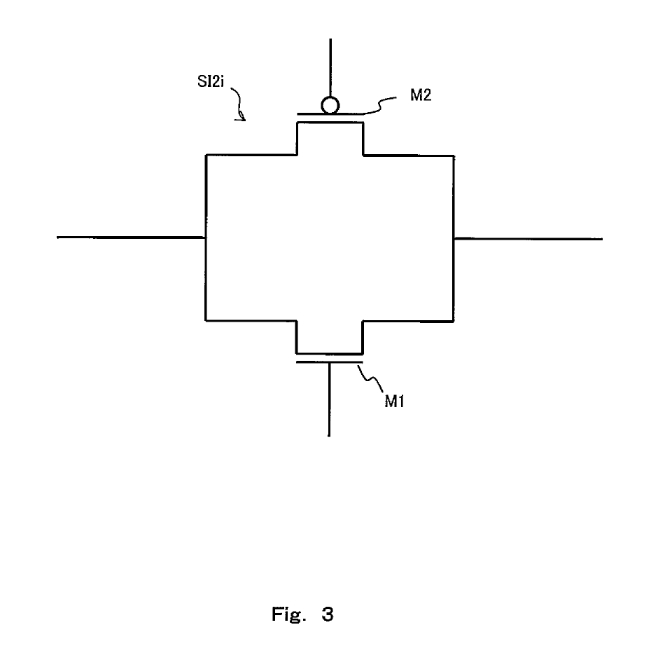

FIG. 3 is a circuit diagram showing an exemplary configuration of the switch used in the D/A converter of FIG. 1. As shown in FIG. 3, each switch is formed by a transfer gate circuit in which a main terminal (drain terminal and source terminal) of a N-type FET M1 and a main terminal (drain terminal and source terminal) of a P-type FET M2 are connected to each other.

By applying a voltage at a predetermined first voltage level (in the example of FIG. 2, H level) to control terminals (gate terminals) of each switch (by applying a voltage at H level to the N-type FET M1 and a voltage at an inverted level (L level) of the first voltage level to the P-type FET M2), a connection is established in each switch (each switch is turned ON). On the other hand, by applying a voltage at a predetermined second voltage level (in the example of FIG. 2, L level lower in voltage than H level) different from the first voltage level to the control terminals (gate terminals) of each switch (by applying a voltage at L level to the N-type FET M1 and a voltage at H level to the P-type FET M2), a disconnection is established in each switch (each switch is turned OFF). As can be seen from FIG. 2, the first switch unit SU1 and the second switch unit SU2 are operative based on clock signals which transition to H level periodically and alternately. Therefore, the first switch unit SU1 and the second switch unit SU2 are turned ON alternately. In a state where all of the switches belonging to the first switch unit SU1 are turned ON, the sampling capacitive elements Ci are charged such that a charging voltage reaches the first reference voltage Vr1 of the first reference voltage source B1 according to the signal levels of the bit signals INi constituting the digital input signal (first period).

The D/A converter 1 further includes an operational amplifier 2 for outputting an analog output signal Vout based on the charging voltage of the sampling capacitive elements Ci. The charging voltage of the sampling capacitive elements Ci is applied to an inverting input terminal of the operational amplifier 2, while a second reference voltage Vr2 of a second reference voltage source B2 is applied to a non-inverting terminal of the operational amplifier 2. It should be noted that the second reference voltage source B2 may be the same as the first reference voltage source B1 (first reference voltage Vr1=second reference voltage Vr2).

The sampling capacitive elements Ci may have an equal capacitance (C1=C2= . . . =CN), or capacitances (Ci=2ⁱ⁻¹C(i−1)) in which a capacitance ratio between the sampling capacitive elements Ci is a binary ratio (2ⁱ⁻¹ times).

In this embodiment, the D/A converter 1 further includes second switch units SU2 which are configured to perform switching to connect the other terminals of the plurality of sampling capacitive elements Ci to the inverting input terminal of the operational amplifier 2 and to disconnect the other terminals of the plurality of sampling capacitive elements Ci from the inverting input terminal of the operational amplifier 2, perform switching to connect the one terminals of the plurality of sampling capacitive elements Ci to each other and to disconnect the one terminals from each other, and perform switching to open and close an electric path through which a voltage according to the voltage of the plurality of sampling capacitive elements Ci with their one terminals connected to each other is output to an output terminal of the operational amplifier 2, in accordance with the switching of the first switch units SU1.

To be specific, as the electric path, the D/A converter 1 has a first path P1 connecting paths between the input terminals Di of the bit signals INi constituting the digital input signal and the one terminals of the sampling capacitive elements Ci, to the output terminal of the operational amplifier 2. The second switch unit SU2 includes an input-side second switch section SI2 provided on the first path P1, and an output-side second switch section SO2 provided between the sampling capacitive elements Ci and the inverting input terminal of the operational amplifier 2. When all of the switches belonging to the first switch unit SU1 are turned OFF and all of the switches belonging to the second switch unit SU2 are turned ON, the operational amplifier 2 outputs the analog output signal (voltage) based on the charging voltage of the sampling capacitive elements Ci (second period). As described above, since the first switch unit SU1 and the second switch unit SU2 transition to H level periodically and alternately, the first period and the second period change periodically. Thus, the D/A converter 1 of this embodiment is a direct-transmission D/A converter.

On an electric path including the sampling capacitive elements Ci and the operational amplifier 2 connected to each other by means of the second switch unit SU2, in this embodiment, on the first path P 1, a resistive element (first resistive element Rs) is provided.

To be specific, the input-side second switch section SI2 includes a plurality of switches SI2i one ends of which are connected to the input terminals Di of the bit signals INi constituting the digital input signal, respectively and the other ends of which are connected to one end of the first resistive element Rs on the first path P1. The other end of the first resistive element Rs is connected to the output terminal of the operational amplifier 2.

In accordance with the above configuration, during an ON-state of the first switch unit SU1, the first reference voltage source B 1 is connected to the sampling capacitive elements Ci, and charges the sampling capacitive elements Ci, according to the signal levels of the corresponding bit signals INi, respectively. Then, when the first switch unit SU1 is turned OFF and the second switch unit SU2 is turned ON, the electric path between the sampling capacitive elements Ci and the operational amplifier 2 is closed. Thereby, the operational amplifier 2 outputs, as the analog output signal Vout, a voltage according to the charging voltage of the plurality of sampling capacitive elements Ci with their one terminals connected to each other. In this case, since the second switch unit SU2 and the first resistive element Rs are present on the first path P1 which is the closed electric path (in this embodiment, the input-side second switch section SI2 and the first resistive element Rs are connected in series), a composite resistance value Ra which affects an output characteristic of the operational amplifier 2 is a sum of a composite resistance value (ON-resistance value) Rsu2 of the second switch unit SU2 and a resistance value Rrs of the first resistive element Rs.

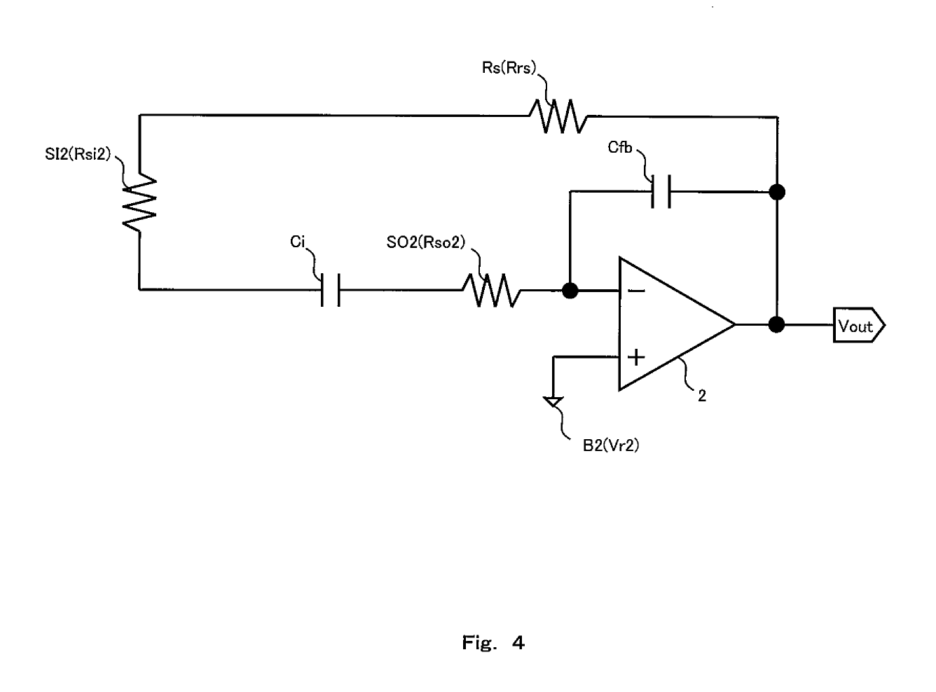

FIG. 4 is a circuit diagram showing an equivalent circuit of the D/A converter 1 of FIG. 1 during the second period. In the circuit of FIG. 4 in which the second switch unit SU2 is turned ON, an ON-resistance component Rsi2 formed by connecting the first resistive element Rs to the input-side second switch section SI2 on the first path P1, an ON-resistance component Rso2 formed by connecting the capacitive element Ci to the output-side second switch section SO2, and a feedback capacitive element Cfb as described later, form a closed loop. Therefore, a composite resistance value Ra in this closed loop is Rsu2 (=Rsi2+Rso2)+Rrs.

Hereinafter, the ON-resistance value of the input-side second switch section SI2 including the FETs will be described. Since the ON-resistance value of the output-side second switch section SO2 is similar to the ON-resistance value of the input-side second switch section SI2, description of it is omitted. The FET used in a transfer gate constituting each switch in the input-side second switch section SI2 has a characteristic (voltage dependency of the ON-resistance value) in which the ON-resistance value changes according to a change in voltage between the gate terminal which is the control terminal and the source or drain terminal which is the main terminal. Therefore, the ON-resistance value (composite resistance value) Rsi2 of the input-side second switch section SI2 changes according to the voltage between both ends of the switch. In this embodiment, in a system in which the input-side second switch section SI2 is connected in series with the first resistive element Rs, the voltage of the analog output signal Vout is applied between both ends of the system. Therefore, the ON-resistance value Rsi2 of the input-side second switch section SI2 changes according to the output voltage value.

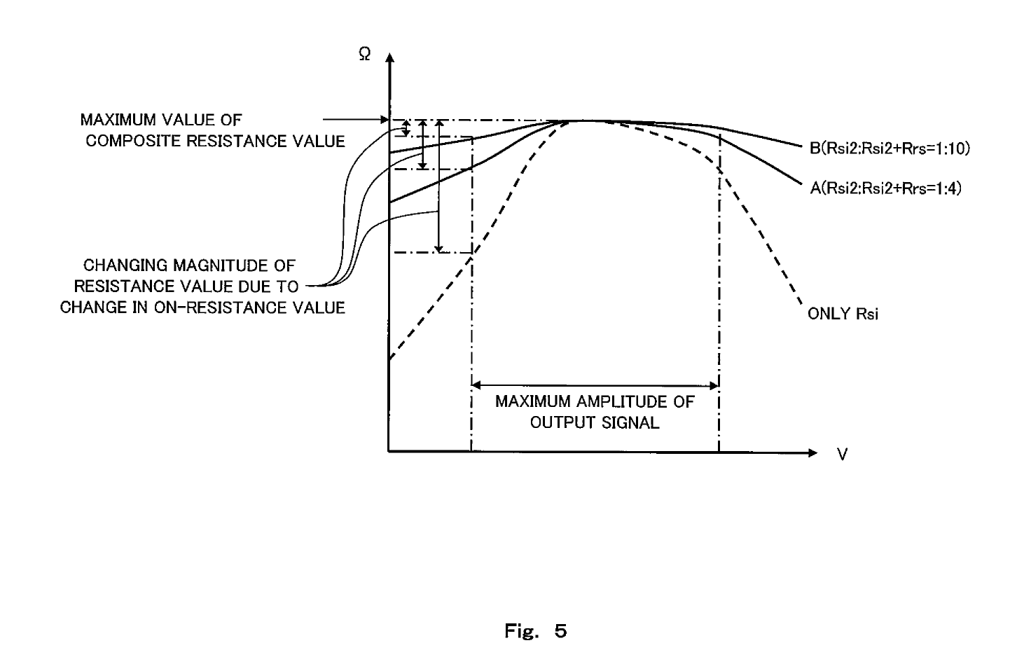

FIG. 5 is a graph showing a change in the composite resistance value of the input-side second switch section SI2 and the resistive element Rs, which change occurs due to a change in the resistance value of the input-side second switch section SI2, in the D/A converter 1 of FIG. 1. For example, in a case where a ratio γ(=(Rsi2+Rrs)/Rsi2) of (Rsi2+Rrs) which is a sum of the resistance value Rsi2 of the input-side second switch section SI2 and the resistance value Rrs of the first resistive element Rs, with respect to a maximum value of the ON-resistance value Rsi2 of the input-side second switch section SI2, is 4 (Rsi2:Rsi2+Rrs=1:4), i.e., a relation is set such that when the sum (Rsi2+Rrs) is 1, the resistance value Rsi2 of the input-side second switch section SI2 is ¼ and resistance value Rrs of the first resistive element Rs is ¾, a changing magnitude of the composite resistance value Ra of the series path (first path P1), which change is due to the fact that the ON-resistance value Rsi2 of the input-side second switch section SI2 changes depending on the voltage, can be significantly suppressed (curve A in FIG. 5), as compared to a configuration in which the first resistive element Rs is omitted (for easier understanding, as indicated by a broken line in FIG. 5, the maximum value of the resistance value Rsi2 of the input-side second switch section SI2 is assumed to be equal to the maximum value of the sum (Rsi2+Rrs) of the resistance values). For example, in another case where the ratio γ(=(Rsi2+Rrs)/Rsi2) of a sum of the first resistance value Rsi2 of the input-side second switch section SI2 and the resistance value Rrs of the first resistive element Rs, with respect to the maximum value of the ON-resistance value Rsi2 of the input-side second switch section SI2, is 10(Rsi2:Rsi2+Rrs=1:10), i.e., a relation is set such that when the sum (Rsi2+Rrs) is 1, the resistance value Rsi2 of the input-side second switch section SI2 is 1/10 and resistance value Rrs of the first resistive element Rs is 9/10, a changing magnitude of the composite resistance value Ra of the series path (first path P1), which change is due to the fact that the ON-resistance value Rsi2 of the input-side second switch section SI2 changes depending on the voltage, can be suppressed more effectively as indicated by a curve B of FIG. 5. For example, when the resistance value Rsi2 of the input-side second switch section SI2 is 200 Ω, the resistance value Rrs of the first resistive element Rs provided on the first path P1 is 1.8 kΩ.

As should be understood from the above, even when the composite resistance value Rsu2 of the second switch unit SU2 including the input-side second switch section SI2 changes according to the voltage applied to the second switch unit SU2, a change rate (Rsu2/Ra=1−Rrs/Ra) of the composite resistance value Ra of the series path is much smaller than a change rate occurring based on only the composite resistance value Rsu2 of the second switch unit SU2 in a configuration where the first resistive element Rs is omitted (in the above formula, if Rrs>>Rsu2, then Rrs≈Ra, which results in Rsu2/Ra→0). Because of this, the operational amplifier 2 can output a more stable analog output signal. Therefore, with a simple configuration, it is possible to prevent a distortion or a noise from being generated in the analog output signal Vout due to the ON-resistance value of the switch. Since in this embodiment, since the first resistive element Rs is connected in series with the output terminal Vout of the operational amplifier 2, it is possible to more effectively prevent a distortion or a noise from being generated in the analog output signal Vout which is the output voltage of the operational amplifier 2.

A preferable range of the ratio γ is 2≦γ≦20, and a more preferable range is 12≦γ≦16. Within this range, it is possible to prevent a distortion or a noise from being generated in the analog output signal while maintaining a response speed permitted in the D/A converter.

In this embodiment, the feedback capacitive element Cfb is provided between the inverting terminal of the operational amplifier 2 and the output terminal of the operational amplifier 2. In this configuration, when the first switch unit SU1 is opened (turned OFF) and the second switch unit SU2 is closed (turned ON), the sampling capacitive elements Ci are connected in parallel with the feedback capacitive element Cfb (with respect to the output terminal of the operational amplifier 2), and distribution of the charge between the sampling capacitive elements Ci and the feedback capacitive element Cfb occurs in such a manner that a part of the charge stored in the sampling capacitive elements Ci is transferred to the feedback capacitive element Cfb. Therefore, when the analog output signal Vout is output, the charge stored in the sampling capacitive elements Ci is transferred from the sampling capactive elements Ci to the feedback capacitive element Cfb through the first path P1 without passing through the operational amplifier 2. This makes it possible to lessen current consumption in the operational amplifier 2.

In particular, in the configuration in which the feedback capacitive element Cfb is provided, when the charge is transferred from the sampling capacitive elements Ci to the feedback capacitive element Cfb, during the second period, the inverting terminal of the operational amplifier 2 is virtually grounded, and therefore, the operational amplifier 2 outputs the analog output signal Vout mainly including a DC voltage applied to the non-inverting terminal. In this case, the operational amplifier 2 must operate so that the output voltage becomes a voltage according to the charge stored in the both ends of the sampling capacitive elements Ci. Note that stability of the D/A converter 1 using the direct-transmission switched-capacitor of this embodiment, depends on a characteristic of the operational amplifier 2, capacitances of the sampling capacitive elements Ci arranged in the vicinity of the operational amplifier 2, the ON-resistance values of the switches arranged in the vicinity of the operation amplifier 2, etc. Therefore, typically, the capacitances of the sampling capacitive elements Ci, and ON-resistances of the switches are set so that a settling time is shortest. If the stability of the D/A converter 1 is low, overshooting, undershooting, ringing, etc., and hence a distortion or a noise would be generated in the analog output signal Vout.

When the second switch unit SU2 is closed (voltage level of the second switch unit SU2 becomes H level), in the input-side second switch section SI2 coupled to the other terminals of the sampling capacitive elements Ci and to the output terminal of the operational amplifier 2, a power supply voltage is applied as a control terminal voltage (gate voltage), and a voltage which is the analog output signal Vout is applied as a main terminal voltage (source or drain voltage). This raises a problem that the value of the ON-resistance of the input-side second switch section SI2 varies depending on the value of the analog output signal Vout, stability of the analog output signal Vout is lessened, and the settling time increases.

The charge according to the output voltage of the operational amplifier 2 which underwent the D/A conversion in a clock cycle which is one-cycle before a current clock was stored in the feedback capacitive element Cfb, immediately before distribution of the charge between the sampling capacitive elements Ci and the feedback capacitive element Cfb is initiated by closing the input-side second switch section SI2. The D/A output voltage resulting from the distribution in one clock cycle entails an error indicated by the following formula (1):

Vni−Vn=(Vni−Vn−1)·(Cfb/(C1+C2+ . . . +CN+Cfb)) (1)

where Vni is an ideal D/A conversion output in a n-th clock cycle, Vn is an actual D/A conversion output in the n-th clock cycle, and Vn−1 is actual D/A conversion output in a (n−1)-th clock cycle.

As a method of reducing the error expressed as the above formula (1), the error may possibly be reduced by performing D/A conversion for one digital input signal In plural times. In this case, it is essential that the D/A converter 1 operate by oversampling. Therefore, there is a need for a shorter settling time.

As described above, in the direct-transmission D/A converter 1, a fluctuation in the ON-resistance value of the input-side second switch section SI2 included in the first path P1 which is a feedback path makes the settling time longer. In addition, in the direct-transmission D/A converter 1, since it is essential that the D/A converter 1 operate by oversampling, the settling time is required to be shorter.

In view of the above, the D/A converter 1 of this embodiment includes the first resistive element Rs on the first path P1 which is the feedback path. This makes it possible to suppress a change in the resistance value in the overall first path P1, even if the ON-resistance value of the input-side second switch section SI2 varies according to the value of the analog output signal Vout. As a result, the settling time can be prevented from becoming longer.

### Embodiment 2

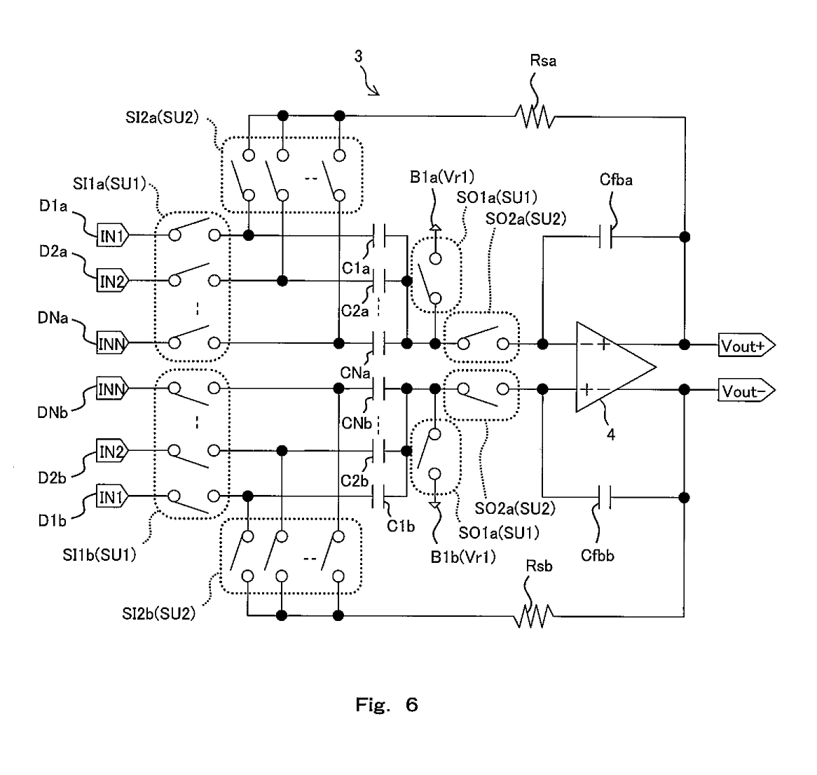

Subsequently, Embodiment 2 of the present invention will be described. FIG. 6 is a circuit diagram showing a schematic configuration of a D/A converter according to Embodiment 2 of the present invention. In Embodiment 2, the same or corresponding constituents or components are designated by the same reference symbols, and will not be described repetitively.

As shown in FIG. 6, a D/A converter 3 of this embodiment is different from the D/A converter 1 of Embodiment 1 in that the operational amplifier 2 of the D/A converter 1 is replaced by a differential operational amplifier 4 having two terminals to which a charging voltage similar to that of Embodiment 1 is input, in the D/A converter 3. To be specific, a charging voltage of sampling capacitive elements Cia is input to the inverting input terminal of the differential operational amplifier 4 according to the bit signals INi constituting the digital input signal, and a non-inverted analog output signal Vout+ is output through the non-inverting output terminal of the differential operational amplifier 4, with the configuration (designated by adding a to the reference symbols in FIG. 6) similar to that of Embodiment 1. In addition, a charging voltage of sampling capacitive elements Cib is input to the non-inverting input terminal of the differential operational amplifier 4 according to the bit signals INi identical to those applied to the inverting input terminal, and an inverted analog output signal Vout− is output through the inverting output terminal of the differential operational amplifier 4, with the configuration (designated by adding b to the reference symbols in FIG. 6) similar to that of Embodiment 1.

Since such a fully differential D/A converter 3 is implemented as described above, an in-phase noise can be removed and D/A conversion can be performed with higher accuracy.

### Embodiment 3

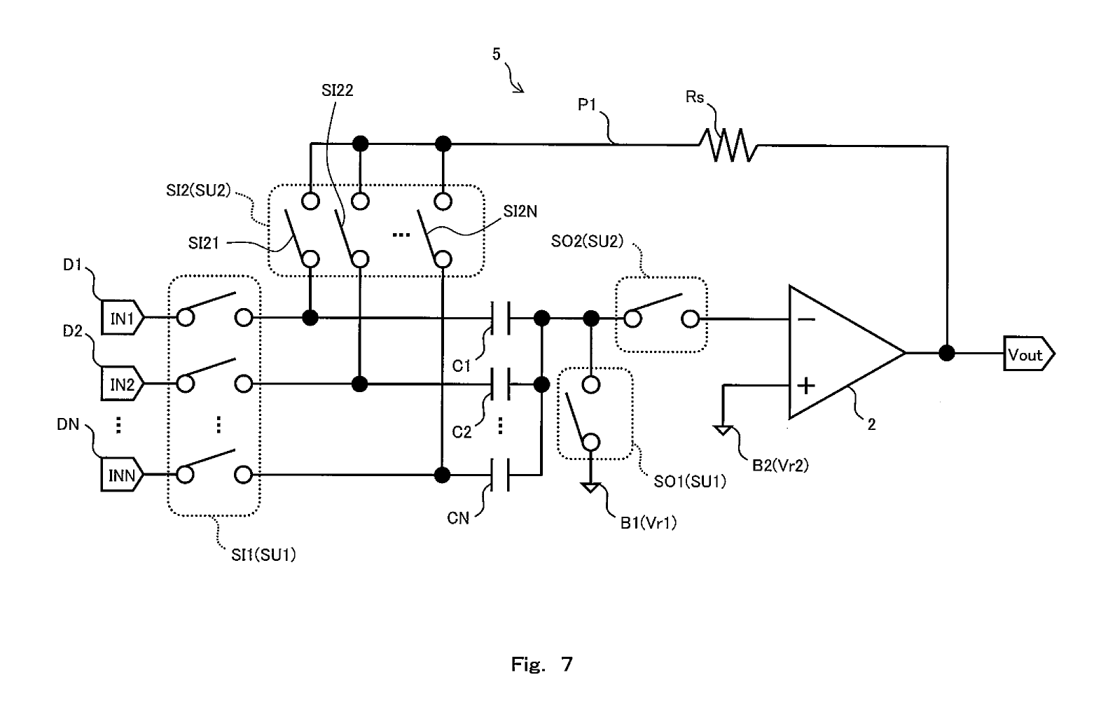

Subsequently, Embodiment 3 of the present invention will be described. FIG. 7 is a circuit diagram showing a schematic configuration of a D/A converter according to Embodiment 3 of the present invention. In Embodiment 3, the same or corresponding constituents or components are designated by the same reference symbols, and will not be described repetitively. As shown in FIG. 7, a D/A converter 5 of this embodiment is different from the D/A converter 1 of Embodiment 1 in that the feedback capacitive element Cfb is omitted in the D/A converter 5. By providing the first resistive element Rs on the first path P1 in a configuration in which distribution of the charge between the sampling capacitive elements Ci and the feedback capacitive element Cfb is not performed, with a simple configuration, it is possible to prevent a distortion or a noise from being generated in the analog output signal Vout due to the ON-resistance value of the switch. In addition, since the first resistive element Rs is connected in series with the output terminal of the operational amplifier 2, it is possible to more effectively prevent a distortion or a noise from being generated in the analog output signal Vout which is the output voltage of the operational amplifier 2.

### Embodiment 4

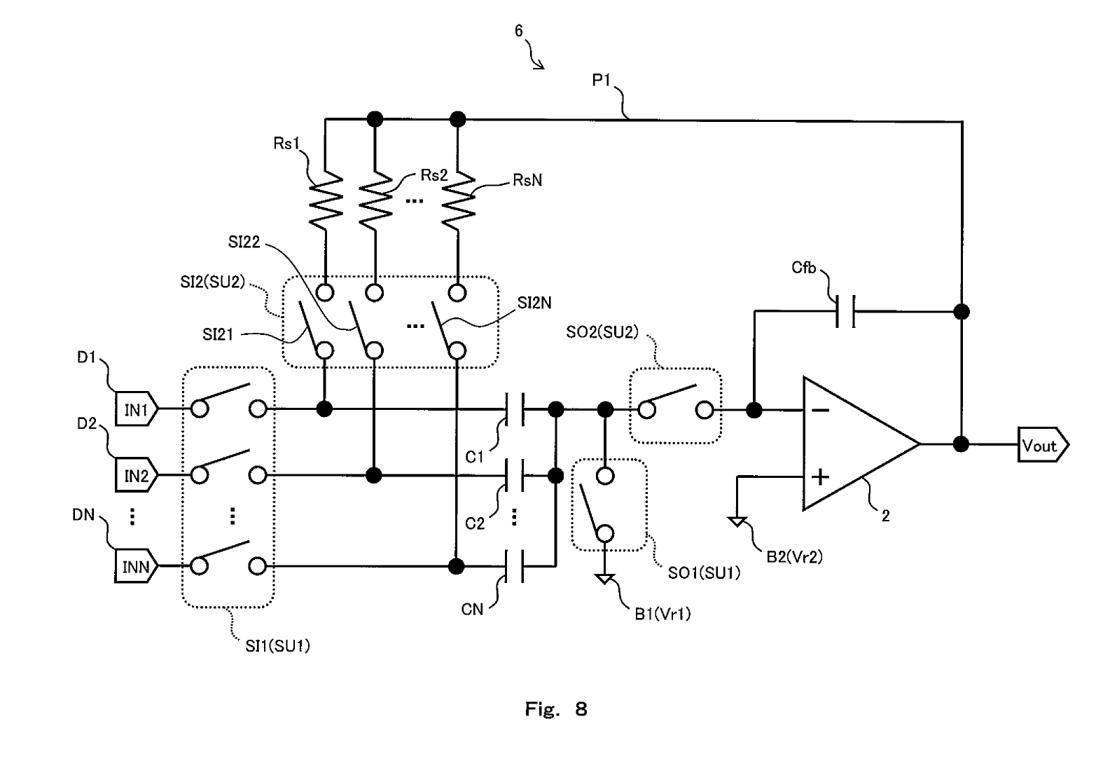

Subsequently, Embodiment 4 of the present invention will be described. FIG. 8 is a circuit diagram showing a schematic configuration of a D/A converter according to Embodiment 4 of the present invention. In Embodiment 4, the same or corresponding constituents or components are designated by the same reference symbols, and will not be described repetitively. As shown in FIG. 8, a D/A converter 6 of this embodiment is different from the D/A converter 1 of Embodiment 1 in that a plurality of first resistive elements Rsi are provided on the first path P1 in such a manner that one ends thereof are connected to a plurality of switches SI2i in a plurality of input-side second switch sections SI2 corresponding to the input terminals Di, respectively, and the other ends thereof are connected to the output terminal of the operational amplifier 2. Since plurality of first resistive elements Rsi are provided to correspond to the plurality of switches, respectively, it is possible to easily set the resistance values adaptively to the capacitances of the sampling capacitive elements Ci or a switch size (ON-resistance value).

### Embodiment 5

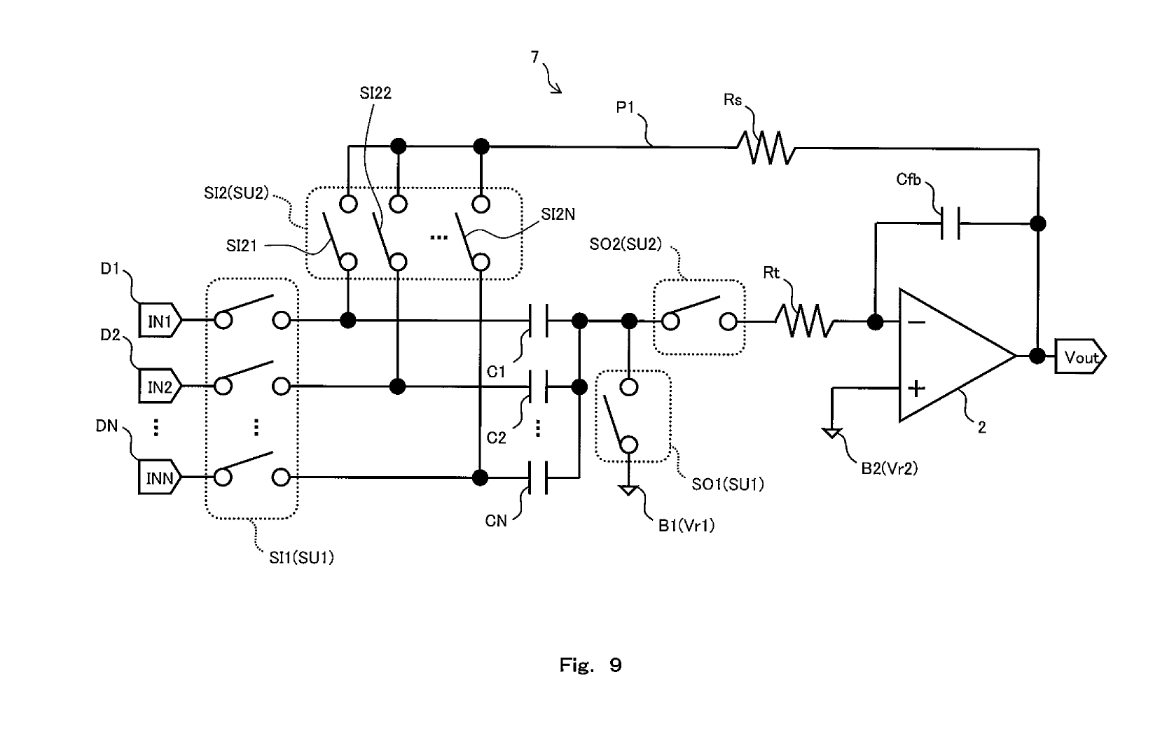

Subsequently, Embodiment 5 of the present invention will be described. FIG. 9 is a circuit diagram showing a schematic configuration of a D/A converter according to Embodiment 5 of the present invention. In Embodiment 5, the same or corresponding constituents or components are designated by the same reference symbols, and will not be described repetitively.

As shown in FIG. 9, a D/A converter 7 of this embodiment is different from the D/A converter 1 of Embodiment 1 in that the resistive element includes a second resistive element Rt provided between the other ends of the sampling capacitive elements Ci and the inverting input terminal of the operational amplifier 2. To be specific, one end of the second resistive element Rt is connected in series with the output-side second switch section SO2 and the other end thereof is connected to the inverting input terminal of the operational amplifier 2. In this configuration, since the second resistive element Rt is connected in series with the inverting input terminal of the operational amplifier 2, the input voltage of the operational amplifier 2 is stabilized, and it is possible to prevent a distortion or a noise from being generated in the analog output signal Vout. Although in this embodiment, the D/A converter 7 includes the first resistive element Rs and the second resistive element Rt, it may include only the second resistive element Rt (the first resistive element Rs may be omitted in the D/A converter 7).

### Embodiment 6

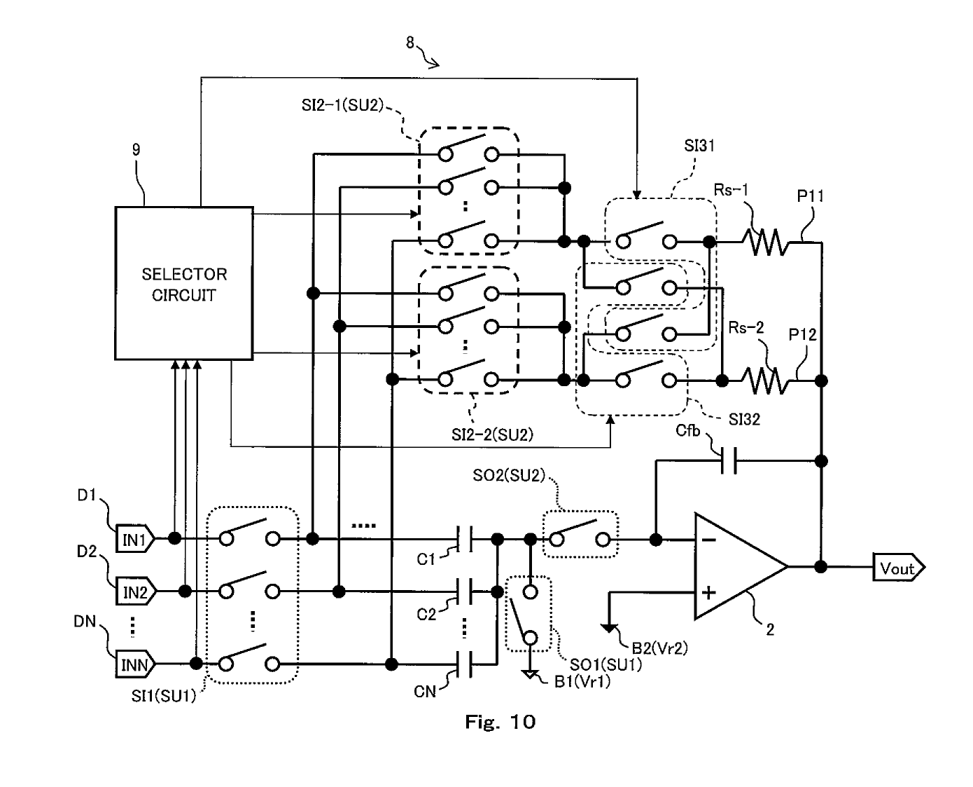

Subsequently, Embodiment 6 of the present invention will be described. FIG. 10 is a circuit diagram showing a schematic configuration of a D/A converter according to Embodiment 6 of the present invention. In Embodiment 6, the same or corresponding constituents or components are designated by the same reference symbols, and will not be described repetitively. As shown in FIG. 10, a D/A converter 8 of this embodiment is different from the D/A converter 1 of Embodiment 1 in that the input-side second switch section SI2 includes a plurality of switches (a plurality of input-side second switch sections SI2-1, SI2-2), the D/A converter 8 detects a signal level (voltage Vr+, Vr−) of the bit signals INi constituting the digital input signal, and a selector circuit 9 is provided to select a switch to be turned ON, from among the plurality of switches SI2-1 and SI2-2, according to a voltage value of the analog output signal Vout which is predicted from the signal level.

Furthermore, in this embodiment, the first resistive element Rs includes a plurality of resistive elements Rs-1 and Rs-2 having different resistance values, the selector circuit 9 detects a signal level of the digital input signal INi, and selects a resistive element (either one of a first path P11 provided with the resistive element Rs-1 or a second path P12 provided with the resistive element Rs-2) to be connected, from among the plurality of resistive elements Rs-1 and Rs-2, according to a voltage value of the analog output signal Vout which is predicted from the signal level. To be specific, the D/A converter 8 includes a first resistive element switch section S131 for performing a switching operation to provide connection and disconnection between the resistive element Rs-1 on the first path P11 and the sampling capacitive elements Ci, and a second resistive element switch section S132 for performing a switching operation to provide connection and disconnection between the resistive element Rs-2 on the second path P12 and the sampling capacitive elements Ci. The first resistive element switch section S131 or the second resistive element switch section S132 is selectively turned ON.

In the above configuration, by predicting the voltage value of the analog output signal Vout of the D/A converter 8 preliminarily, it is possible to predict a composite resistance value of a closed loop including the second switch unit SU2 and the resistive element Rs1/Rs2 during the second period. The selector circuit 9 can predict the voltage value (composite resistance value based on the voltage value of the analog output signal Vout) of the analog output signal Vout, and select a switch having a suitable ON-resistance value which is to be turned ON and/or a resistive element having a suitable resistance value which is to be connected, according to the predicted voltage value.

Although in this embodiment, the switch is selected from among two kinds of switches and the resistive element is selected from among two kinds of resistive elements, the switch is selected from among three or more kinds of switches and the resistive element is selected from among three or more kinds of resistive elements. In a further alternative, only either the switch or the resistive element may be switched.

### Embodiment 7

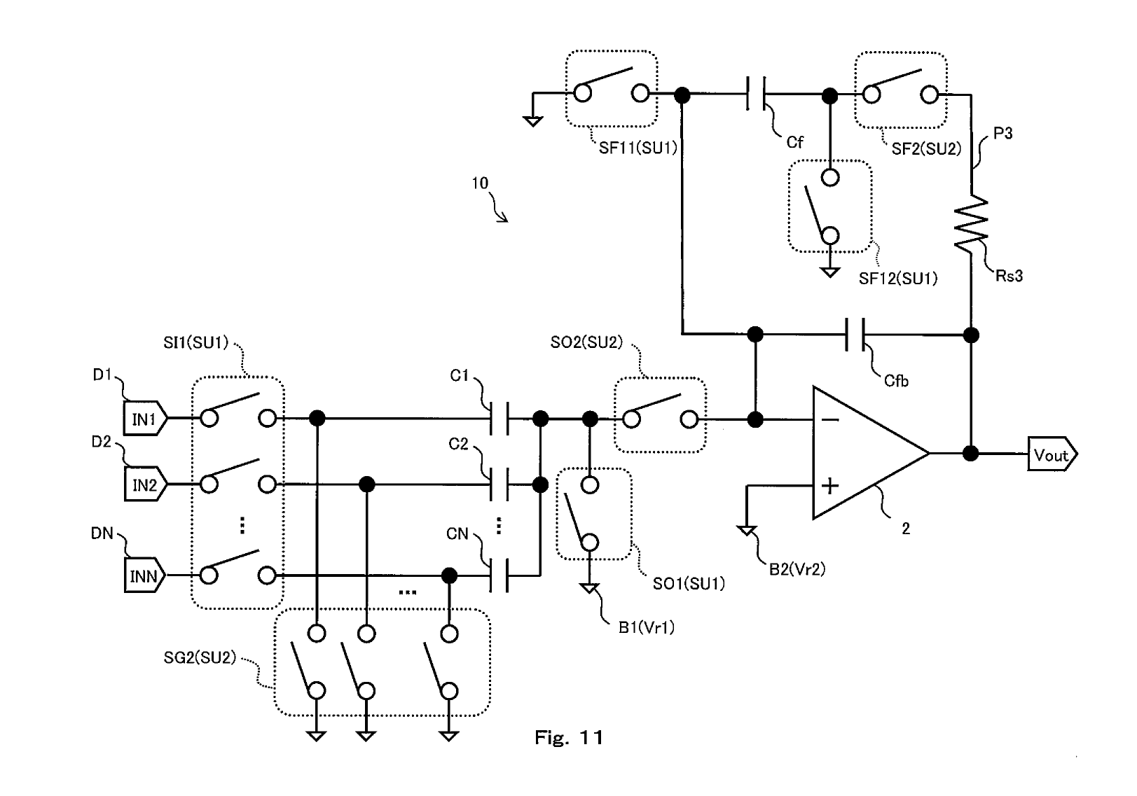

Subsequently, Embodiment 7 of the present invention will be described. FIG. 11 is a circuit diagram showing a schematic configuration of a D/A converter according to Embodiment 7 of the present invention. In Embodiment 7, the same or corresponding constituents or components are designated by the same reference symbols, and will not be described repetitively. As shown in FIG. 11, a D/A converter 9 of this embodiment is different from the D/A converter 1 of Embodiment 1 in that the output terminal of the operational amplifier 2 is not connected to the input terminal side of the sampling capacitive elements Ci (D/A converter 9 is not direct-transmission type D/A converter).

To be specific, the D/A converter 9 includes the sampling capacitive elements Ci, the operational amplifier 2 and the feedback capacitive element Cfb which are similar to those of Embodiment 1, a feedback second switch section SF2 closed during the second period, a second feedback capacitive element Cf connected in parallel with the feedback capacitive element Cfb by closing the feedback second switch section SF2 during the second period, a ground-side second switch section SG2 for grounding the input terminal sides of the sampling capacitive elements Ci (connecting the input terminal sides of the sampling capacitive elements Ci to predetermined voltage sources, respectively), and feedback first switch sections SF11 and SF12 for grounding the both ends of the second feedback capacitive element Cf (connecting the both ends of the second feedback capacitive element Cf to predetermined voltage sources, respectively) during the first period. Furthermore, the D/A converter 9 includes a third resistive element Rs3 provided on an electric path P3 provided with the second feedback capacitive element Cf

In accordance with this configuration, when the first switch unit SU1 (SI1, SO1, SF11, SF12) is turned ON, and the second switch unit SU2 (SG2, SO2, SF2) is turned OFF, during the first period, the sampling capacitive elements Ci are charged according to the signal levels of the corresponding bit signals INi, respectively, and the charge stored in the second feedback capacitive element Cf is discharged. Thereafter, when the first switch unit SU1 is turned OFF and the second switch unit SU2 is turned ON during the second period, distribution of the charge among the sampling capacitive elements Ci and the feedback capacitive elements Cfb and Cf occurs in such a manner that a part of the charge stored in the sampling capacitive elements Ci is transferred to the feedback capacitive elements Cfb and Cf, and the operational amplifier 2 outputs a voltage (analog output signal Vout).

In this embodiment, since the third resistive element Rs3 is provided on the electric path P3 including the sampling capacitive elements Ci and the operational amplifier 2 and closed by the second switch unit SU2, a composite resistance value of the electric path P3 which affects the output characteristic of the operational amplifier 2 is a sum of a composite resistance value (ON-resistance value) of the second switch unit SU2 and a resistance value of the third resistive element Rs3. In this configuration, a change rate of the composite resistance value of the electric path P3 is less than a change rate based on only the composite resistance value of the second switch unit SU2 in a configuration in which the third resistive element Rs3 is omitted. Because of this, the operational amplifier 2 can output a more stable analog output signal Vout. Therefore, in the D/A converter 9 of this embodiment, which is not a direct transmission type, it is possible to prevent a distortion or a noise from being generated in the analog output signal Vout due to the ON-resistance value of the switch, with a simple configuration.

In a configuration other than the D/A converter 9 of FIG. 11, in which a switch is provided on a path (i.e., path connected to the operational amplifier 2 during the second period) which affects stability of the output voltage of the operational amplifier 2, similar advantages can be achieved by providing a resistive element in series with the switch.

### APPLICATION EXAMPLES OF D/A CONVERTER

### Application Example 1

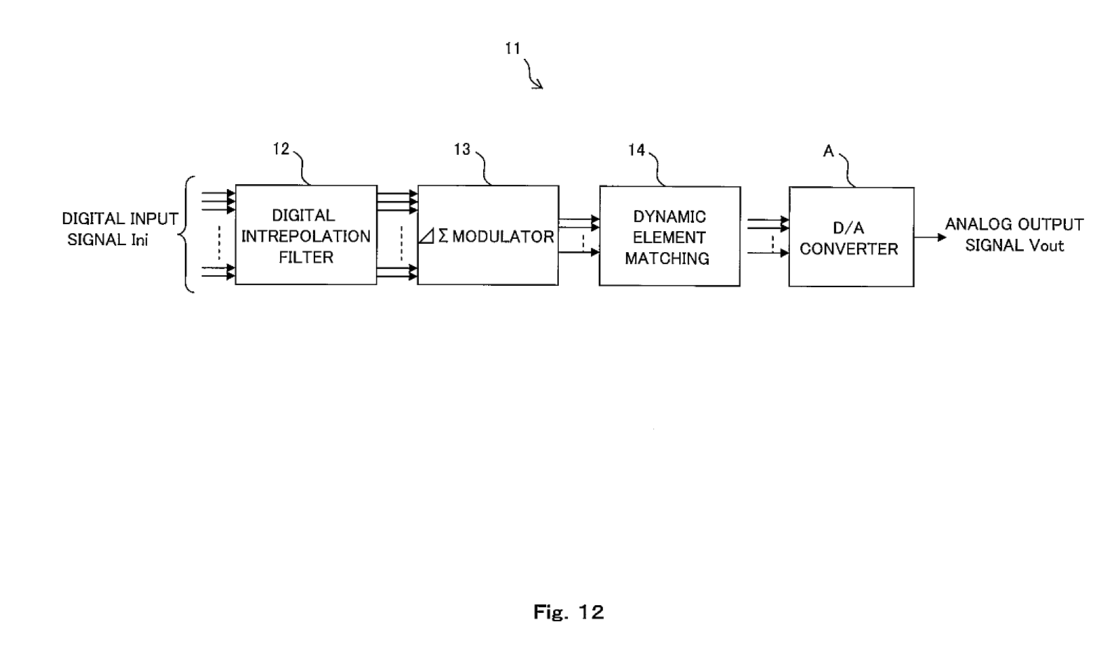

Next, examples of D/A converting devices incorporating the D/A converters 1, 3, 5, 7, 8, and 10 of the above described embodiments will be descried. FIG. 12 is a circuit diagram showing an exemplary schematic configuration of a D/A converting device incorporating the D/A converter of the present invention. Referring to FIG. 12, a D/A converting device 11 of Application Example 1 includes a digital interpolation filter 12 which interpolates a plurality of bit signals Ini constituting a digital input signal, a delta-sigma modulator 13 for delta-sigma modulating the interpolated plurality of bit signals Ini, and a D/A converter A (one of the D/A converters 1, 3, 5, 7, 8, and 10) which has the above described configuration and converts the plurality of delta-sigma modulated bit signals Ini into an analog signal.

In accordance with this configuration, since the delta-sigma modulated bit signals Ini are converted into the analog signal using the D/A converter A having the above configuration, the operational amplifier 2 or 4 of the D/A converter A can output a more stable analog output signal Vout. Especially, when the delta-sigma modulator 13 performs delta-sigma modulation, a sampling frequency becomes high because of execution of the oversampling. For this reason, the D/A converter A is required to operate at a high speed (with high resolution and short settling time). However, the high-speed operation of the D/A converter A is impeded by a phenomenon such as ringing occurring in the D/A converter A. By incorporating the D/A converter A having the above configuration into the D/A converting device 11 which performs the delta-sigma modulation, a stable analog output signal Vout can be output even when the delta-sigma modulation is performed with a high sampling frequency.

The D/A converting device 11 of this embodiment further includes a dynamic element matching section 14 which performs a dynamic element matching process with respect to the delta-sigma modulated digital signals (a plurality of bit signals) output from the delta-sigma modulator 13. The digital signals (a plurality of bit signals) which has undergone the dynamic element matching process are input to the D/A converter A. The dynamic element matching process can suppress a variation in capacitances of the sampling capacitive elements Ci in the D/A converter A. Therefore, the D/A converter A can output a more stable analog output signal Vout.

### Application Example 2

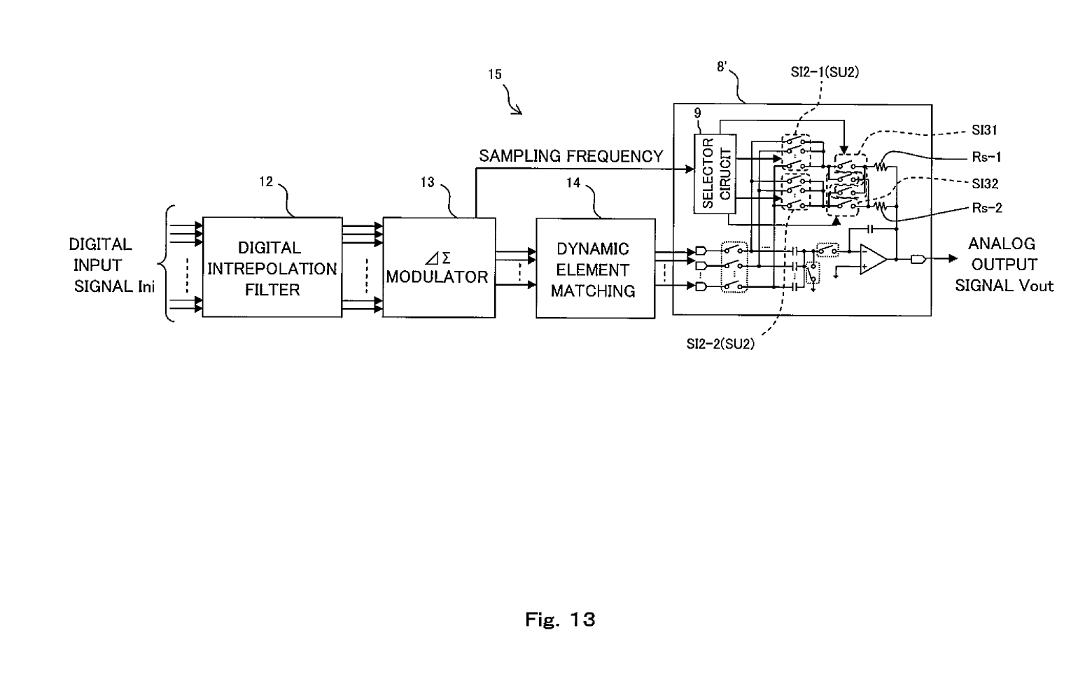

Subsequently, an example of a D/A converting device incorporating a modification example of the D/A converter 8 including the selector circuit 9, among the D/A converters of the above embodiments, will be described. FIG. 13 is a circuit diagram showing another exemplary schematic configuration of the D/A converting device incorporating the D/A converter of the present invention. Referring to FIG. 13, a D/A converting device 15 of application example 2 is different from the D/A converting device 11 of application example 1 shown in FIG. 12 in that an input-side second switch section of a D/A converter 8′ includes a plurality of input-side switch sections SI2-1 and SI2-2 having different ON-resistance values, a resistive element includes a plurality of resistive elements Rs-1 and Rs-2 having different resistance values, and the selector circuit 9 selects a switch to be turned ON, from among the plurality of input-side switch sections SI2-1 and SI2-2, and a resistive element to be connected, from among the plurality of resistive elements Rs-1 and Rs-2, according to a sampling frequency used in the sigma-delta modulator 13. The resistive element Rs-1 or Rs-2 is switched to be connected, by selectively closing the corresponding resistive element switch section SI31, or SI32, respectively, like Embodiment 6.

As described above, the sampling frequency used in the delta-sigma modulator 13 affects the resolution and settling time of the D/A converter 8′ positioned in a subsequent stage and coupled to the delta-sigma modulator 13. The selector circuit 9 selects a switch having a more suitable ON-resistance value, from among the plurality of input-side second switch sections S12-1 and S12-2, and a resistive element having a more suitable resistance value, from among the plurality of resistive elements Rs-1 and Rs-2 according to the sampling frequency used in the delta-sigma modulator 13, and in this state, discharging of the sampling capacitive elements Ci is performed. Because of this, the operational amplifier 2 can output a more stable analog output signal Vout. To be specific, when a higher sampling frequency is set, a switch having a lower ON-resistance value and a resistive element having a lower resistance value are selected.

Moreover, in this embodiment, only either the input-side second switch sections SI2-1 and SI2-2 or the resistive elements Rs-1 and Rs-2 may be configured to be switched, according to the sampling frequency used in the delta-sigma modulator 13, or the number of switches and/or the number of resistive elements may be set to three or more.

Thus far, embodiments and modification examples thereof the present invention have been described. The present invention is not limited to them, but can be improved, altered or modified, within a scope of the invention. For example, constituents in the above embodiments and modification examples may be combined as desired.

A D/A converter and a D/A converting device of the present invention are useful because they are capable of preventing a distortion or a noise from being generated in the analog output signal, due to an ON-resistance value of a switch, with a simple circuit configuration.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

What is claimed is:

1. A digital-to-analog converter comprising:
a plurality of input terminals to which a plurality of bit signals constituting a digital signal are input, respectively;
a plurality of sampling capacitive elements provided to correspond to the plurality of input terminals, respectively;
a first switch unit for performing switching to connect one terminals of the plurality of sampling capacitive elements to the corresponding plurality of input terminals, respectively, and to disconnect the one terminals of the plurality of sampling capacitive elements from the corresponding plurality of input terminals, respectively, and performing switching to connect the other terminals of the plurality of sampling capacitive elements to a reference voltage source for generating a reference voltage and to disconnect the other terminals of the plurality of sampling capacitive elements from the reference voltage source;
an operational amplifier having a non-inverting input terminal applied with the reference voltage of the reference voltage source;
a second switch unit for performing switching to connect the other terminals of the plurality of sampling capacitive elements to an inverting input terminal of the operational amplifier, and to disconnect the other terminals of the plurality of sampling capacitive elements from the inverting input terminal, performing switching to connect the one terminals of the plurality of sampling capacitive elements to each other and to disconnect the one terminals of the plurality of sampling capacitive elements from each other, and performing switching to close and open an electric path through which a voltage according to a voltage of the plurality of sampling capacitive elements with the one terminals connected to each other, is output to an output terminal of the operational amplifier, in accordance with the switching of the first switch unit; and
a resistive element provided on the electric path.

2. The digital-to-analog converter according to claim 1,
wherein the resistive element includes a first resistive element provided on a first path connecting paths between the plurality of input terminals and the one terminals of the plurality of sampling capacitive elements to the output terminal of the operational amplifier; and
the second switch unit includes an input-side second switch section provided on the first path and an output-side second switch section provided between the other terminals of the plurality of sampling capacitive elements and the inverting input terminal of the operational amplifier.

3. The digital-to-analog converter according to claim 2,
wherein a ratio of a sum of a composite resistance value of the input-side second switch section and a resistance value of the first resistive element with respect to a maximum value of the composite resistance value of the input-side second switch section is not less than 2 and not more than 20.

4. The digital-to-analog converter according to claim 3,
wherein the ratio is not less than 12 and not more than 16.

5. The digital-to-analog converter according to claim 2,
wherein the input-side second switch section includes a plurality of switches corresponding to the plurality of sampling capacitive elements, respectively; and
the first resistive element includes a plurality of first resistive elements, one ends of which are connected to the plurality of switches in the input-side second switch section, respectively, and the other ends of which are connected to the output terminal of the operational amplifier.

6. The digital-to-analog converter according to claim 1, further comprising:
a feedback capacitive element provided between the inverting input terminal of the operational amplifier, and the output terminal of the operational amplifier.

7. The digital-to-analog converter according to claim 1,
wherein the resistive element includes a second resistive element provided between the other terminals of the sampling capacitive elements and the inverting input terminal of the operational amplifier.

8. The digital-to-analog converter according to claim 2,
wherein the input-side second switch section includes a plurality of switches having different ON-resistance values, the digital-to-analog converter further comprising:
a selector circuit which detects a signal level of the digital input signal and selects a switch to be turned ON, from among the plurality of switches, based on a voltage value of the analog output signal which is predicted from the detected signal level.

9. The digital-to-analog converter according to claim 1,
wherein the resistive element includes a plurality of resistive elements having different resistance values, the digital-to-analog converter further comprising:
a selector circuit which detects a signal level of the digital input signal and selects a resistive element to be connected, from among the plurality of resistive elements, based on a voltage value of the analog output signal which is predicted from the detected signal level.

10. A digital-to-analog converting device comprising:
a digital interpolation filter for interpolating a digital input signal and outputting the interpolated digital input signal;
a delta-sigma modulator for delta-sigma modulating the interpolated digital input signal; and
a digital-to-analog converter for converting the delta-sigma modulated digital input signal into an analog signal; the digital-to-analog converter including:
a plurality of input terminals to which a plurality of bit signals constituting a digital signal are input, respectively;
a plurality of sampling capacitive elements provided to correspond to the plurality of input terminals, respectively;
a first switch unit for performing switching to connect one terminals of the plurality of sampling capacitive elements to the corresponding plurality of input terminals, respectively, and to disconnect the one terminals of the plurality of sampling capacitive elements from the corresponding plurality of input terminals, respectively, and performing switching to connect the other terminals of the plurality of sampling capacitive elements to a reference voltage source for generating a reference voltage and to disconnect the other terminals of the plurality of sampling capacitive elements from the reference voltage source;
an operational amplifier having a non-inverting input terminal applied with the reference voltage of the reference voltage source;
a second switch unit for performing switching to connect the other terminals of the plurality of sampling capacitive elements to an inverting input terminal of the operational amplifier, and to disconnect the other terminals of the plurality of sampling capacitive elements from the inverting input terminal, performing switching to connect the one terminals of the plurality of sampling capacitive elements to each other and to disconnect the one terminals of the plurality of sampling capacitive elements from each other, and performing switching to close and open an electric path through which a voltage according to a voltage of the plurality of sampling capacitive elements with the one terminals connected to each other, is output to an output terminal of the operational amplifier, in accordance with the switching of the first switch unit; and
a resistive element provided on the electric path.

11. The digital-to-analog converting device according to claim 10,
wherein the resistive element includes a first resistive element provided on a first path connecting paths between the plurality of input terminals and the one terminals of the plurality of sampling capacitive elements to the output terminal of the operational amplifier; and
the second switch unit includes an input-side second switch section provided on the first path and an output-side second switch section provided between the other terminals of the plurality of sampling capacitive elements and the inverting input terminal of the operational amplifier.

12. The digital-to-analog converting device according to claim 11,
wherein a ratio of a sum of a composite resistance value of the input-side second switch section and a resistance value of the first resistive element with respect to a maximum value of the composite resistance value of the input-side second switch section is not less than 2 and not more than 20.

13. The digital-to-analog converting device according to claim 12,
wherein the ratio is not less than 12 and not more than 16.

14. The digital-to-analog converting device according to claim 11,
wherein the input-side second switch section includes a plurality of switches corresponding to the plurality of sampling capacitive elements, respectively; and
the first resistive element includes a plurality of first resistive elements, one ends of which are connected to the plurality of switches in the input-side second switch section, respectively, and the other ends of which are connected to the output terminal of the operational amplifier.

15. The digital-to-analog converting device according to claim 10, further comprising:
a feedback capacitive element provided between the inverting input terminal of the operational amplifier, and the output terminal of the operational amplifier.

16. The digital-to-analog converting device according to claim 10,
wherein the resistive element includes a second resistive element provided between the other terminals of the sampling capacitive elements and the inverting input terminal of the operational amplifier.

17. The digital-to-analog converting device according to claim 10,
wherein the input-side second switch section includes a plurality of switches having different ON-resistance values, the digital-to-analog converter further comprising:
a selector circuit which detects a signal level of the digital input signal and selects a switch to be turned ON, from among the plurality of switches, based on a voltage value of the analog output signal which is predicted from the detected signal level.

18. The digital-to-analog converting device according to claim 10,
wherein the resistive element includes a plurality of resistive elements having different resistance values, the digital-to-analog converter further comprising:
a selector circuit which detects a signal level of the digital input signal and selects a resistive element to be connected, from among the plurality of resistive elements, based on a voltage value of the analog output signal which is predicted from the detected signal level.

19. The digital-to-analog converting device according to claim 10, further comprising:
a dynamic element matching section for performing a dynamic element matching process with respect to the delta-sigma modulated digital signal output from the delta-sigma modulator, the digital signal that has undergone the dynamic element matching process, being input to the digital-to-analog converter.

20. The digital-to-analog converting device according to claim 11,
wherein the input-side second switch section includes a plurality of switches having different ON-resistance values;
the resistive element includes a plurality of resistive elements having different resistance values; and
the selector circuit selects a switch to be turned ON, from among the plurality of switches and a resistive element to be connected, from among the plurality of resistive elements, according to a sampling frequency used in the delta-sigma modulator.
